(19) United States
(12) Patent Application Publication
(10) Pub. No.: US 2004/0070083 A1
(43) Pub. Date: Apr. 15, 2004

(54) Stacked flip-chip package

(76) Inventor: Huan-Ping Su, Hsinchu (TW)

Correspondence Address: ANDERSON KILL & OLICK, P.C., 1251 Avenue of the Americas, New York, NY, 10020, US

(21) Appl. No.: 10/650,196

(22) Filed: Aug. 26, 2003

(30) Foreign Application Priority Data
Oct. 15, 2002 (TW) 091123663

(51) Int. Cl. H01L 23/48; H01L 23/52; H01L 29/40

(52) U.S. Cl. 257/778

(57) ABSTRACT

A stacked flipchip package is disclosed comprising two chip carriers, each of which includes at least a chip and a plurality of solder bumps formed on the active surface of the chip used to electrically connect the chip to the chip carrier. A first chip carrier is joined “back to back” with a second chip carrier via an insulating adhesive applied on the inactive surface of the first chip mounted on the first chip carrier and the inactive surface of the second chip mounted on the second chip carrier. Wherein the two inactive surfaces are bonded together to form a multichip module. Both the topmost surface and the lowermost surface of the multichip module are capable of being electrically connected with other components, thereby eliminating one of the obstacles associated with vertically stacking chips in flip-chip technology and further varying arrangement flexibility of the chips in a package.

### FIELD OF THE INVENION

The present invention relates to multichip semiconductor packages, and, more particularly, to a flipchip semiconductor package having at least two chips stacked vertically.

### BACKGROUND OF THE INVENTION

In order to achieve higher performance and greater functionality for electronic products, semiconductor packages are developed to be highly integrated with more electronic components being incorporated in a fixed-sized chip. However, forming highly integrated semiconductor chips requires considerably advanced fabrication technology, which thereby limits the availability and applicability for such highly integrated chips. Therefore, in order to improve the functionality and capacity of a single semiconductor package, forming semiconductor packages using multichip modules has become more and more desirable.

A semiconductor package comprising a multichip module is formed by placing at least two semiconductor chips on a chip carrier such as a substrate or a lead frame. Generally, this chip-to-chip carrier bonding can be accomplished in two ways. One way is by spacing and adhering the chips on a substrate. Although this method does not increase the overall height of the package, it requires a larger surface area for the substrate carrier in order to incorporate all the chips, thus making it difficult to form a semiconductor package with reduced size. Moreover, as the chip carrier becomes larger in size, more thermal stress is generated when electrical connection is made between the packaged device and external electronic devices such as a printed circuit board, which, in turn, adversely permits delamination or peeling between the chip and the chip carrier, thereby creating more reliability concerns. Alternatively, another way to interconnect chips to a chip carrier is by stacking semiconductor chips vertically on a chip carrier. This method, by comparison, typically increase the overall height of the semiconductor package, but can desirably prevent chip carrier warpage or delamination, and thus is often preferred by manufacturers in the semiconductor industry.

A stacked multichip semiconductor package 4, as shown in FIG. 5, is formed by adhering a second chip 44 on top of a first chip 41 which is firstly adhered on a substrate 40, and then electrically connecting the first chip 41 and the second chip 44 to the substrate 40 via the first gold wires 42 and the second gold wires 45 respectively. In order to prevent the second chip 44 from interfering with the bonding between the first chip 41 and the first gold wires 42, the second chip 44 is often manufactured to have a smaller size than that of the first chip 41. However, this size reduction decreases the functionality of chips using this solution due to the reduced area for components.

In order to overcome the limitation on the size of the for the second chip, U.S. Pat. No. 5,793,108 discloses a semiconductor package with a multichip module as a solution. As shown in FIG. 6, the first chip 41 of this semiconductor package 4 is adhered on the chip pad 400 of the lead frame 40 via its active surface 410, and the first gold wires 42 are provided to electrically connect the first chip 41 to the lead fingers 401 of the lead frame 40. Then, the non-active surface 441 of the second chip 44 is adhered to the non-active surface 411 of the second chip 41, and the second gold wires 45 are provided to electrically connect the second chip 44 to the lead fingers 401 of the lead frame 40. This back-to-back bonding method avoids reducing the size of the second chip 44; however, the electrical connections for the first chip 41 and the second chip 44 to the lead fingers 401 of the lead frame 40—each of which requires a wire bonding process—increases the overall thickness of the semiconductor package due to the combination of loop heights for the first gold wires 42 and the second gold wires 45. Moreover, the loop wires might be swept when subjected to the impact of the molding flow, otherwise known as wire sweeping, which, in turn makes the bonding reliability even worse.

In order to overcome the problems associated with wire bonding and also given consideration to the number of inputs and outputs required, a further improved technology for the ball grid array, has been developed and become widely used in the semiconductor industry. Flip-chip technology is characterized by inversely attaching a semiconductor chip with a plurality of solder bumps formed on the active surface thereof at the wafer stage to a substrate having a plurality of fingers formed thereon at positions opposing the solder bumps, by means of applying two reverse-bond techniques to form a so-called chip-solder bumps-substrate structure. However, the current flip chip semiconductor package, just like the above-mentioned ball grid array semiconductor package and lead finger connected package can only be electrically connected to the substrate via the active surface of the chip. Thus, if a stacked semiconductor package with multichip module is to be desirably produced, while the chip can only be electrically connected to the substrate via only one surface i.e.) the active surface thereof, the U.S. Pat. No. 6,404,043 further discloses a novel flip chip multichip module in order to prevent inappropriate electrical connection,

As shown in FIG. 8, this multichip module comprises two conductive layers, a first chip conductive layer 50 and a second conductive layer 53, which are respectively connected to a first chip 51 and a second chip 54 in a flip-chip manner. The multichip module also comprises an interconnect frame 56 disposed between the first conductive layer 50 and the second conductive layer 53 for electrically connecting the two. The interconnect fame 56 has a plurality of openings 560 formed for accommodating the first chip 51 therein after the first conductive layer 50 has been jointed to the interconnect frame. The multichip module further comprises a single layered substrate 58 on which the first conductive layer 50 is adhered thereon allowing the first chip 51 and the second chip 54 to be electrically connected to the substrate 58 via the two conductive layers 50 and 53 and the interconnect frame 56. The package can be electrically connected to external electronic devices via this substrate 58. With the provision of the interconnect frame 56, the first chip 51 and the second chip 54 can be respectively connected to the substrate 58 in a flip-chip manner, forming an upright multichip module 5′. However, in order to avoid damage to the first chip 51 caused by compression of the second conductive layer 53, the height of the interconnect frame must be higher than that of the first chip 51. Since the height of the mutichip module 5′ consists of relatively thick interconnect lead frame 56, it is difficult to reduce the overall height of the multichip module 5.

### SUMMARY OF THE INVENTION

A primary objective of the present invention is to provide a flipchip semiconductor package having at least two semiconductor chips being stacked vertically and electrically connected to a chip carrier, in which the overall height and volume of the semiconductor package is further reduced.

Another objective of the present invention is to provide a multichip stacked flipchip semiconductor package having shorter signal paths and reliable electrical bonding qualities between the chip and the chip carrier.

Further, another objective of the present invention is to provide a multichip stacked flipchip semiconductor package in which lower resin materials replace conventional encapsulating materials to facilitate a one-step encapsulating process, allowing the encapsulating process to be simplified as well as preventing so-called popcorn effect from occurring.

In order to achieve the foregoing objectives and other objectives, one embodiment of the present invention provides a multi-flipchip semiconductor package, comprising: a first chip carrier accommodating at least one first chip having an active surface on which a plurality of solder bumps are formed for electrically connecting the first chip to first chip carrier, and an opposing non-active surface; a second chip carrier accommodating at least one second chip having an active surface on which a plurality of solder bumps are formed for electrically connecting the second chip to the second chip carrier and an opposing non-active surface; an insulating adhesive layer, applied over the non-active surface of the first chip, allowing the second chip carrier to be attached in a back-to-back manner to the non-active surface of the first chip; a resin encapsulating layer, filling the gaps in between the first chip carrier and the second chip carrier for encapsulating the first chip, the second chip, and the solder bumps formed on the two chips; and a plurality of conductive vias which extend axially between the first chip carrier, resin encapsulating layer and second chip carrier, allowing signals from the second chip to be conducted to the first chip carrier by way of the vias.

The flipchip semiconductor package in accordance with another embodiment of the present invention is proposed, in which at least two multichip modules of the foregoing embodiment is stacked vertically. The first chip substrate of the topmost multichip module is electrically connected to the second chip substrate of the lowermost multichip module via a plurality of solder bumps, allowing the first chip and the second chip being encapsulated within the topmost multichip module to be electrically connected to the first chip substrate of the bottommost multichip module. The first chip substrate of the bottommost multichip module then is electrically connected to external devices via a plurality of solder balls mounted on the back side thereof.

In comparison with prior art, the first chip carrier can be joined back-to-back with a second chip carrier with a provision of conductive metal layer that connects the first chip substrate and the second chip carrier. This can be advantageous because a reserved cavity for accommodating chips is not necessarily required, allowing the overall height of the package to be further reduced which coincides with the ongoing demand for reduced package size. Moreover, all the chips in the invention are attached using flip-chip attachment, which provides preferable electrical connection quality, and, thereby, reduces any bonding reliability concerns.

Also, because the attachment between the first chip carrier and the second chip carrier is achieved in a back-to-back manner, this flipchip semiconductor package can be utilized as a multichip module having a substrate layer with bond pads disposed on both the upper and lower surface thereof, and thus can be used in combination with other arrangements.

Moreover, the resin encapsulating layer between the first chip carrier and the second chip carrier is selected from a group of resin materials having low hygrosocopicity such as epoxy; therefore, after encapsulation, the encapsulating layer will not generate the popcorn problem which sometimes appears during the latter testing process due to the absorption of excessive moisture. Also, as the resin encapsulating materials has greater fluidity compared to conventional materials, the resin materials can be underfilled, thereby effectively preventing the occurrence of voids.

### BRIEF DESCRIPTION OF THE DRAWINGS

The invention can be more fully understood by reading the following detailed description of the preferred embodiments, with reference made to the accompanying drawings, wherein:

FIG. 1 is a cross-sectional schematic diagram showing a flipchip semiconductor package in accordance with the first preferred embodiment of the invention;

FIG. 2 is a partition schematic diagram showing the flipchip semiconductor package in accordance with the first preferred embodiment of the invention;

FIG. 3 is a cross-sectional schematic diagram showing the flipchip semiconductor package in accordance with the second preferred embodiment of the invention;

FIG. 4A and FIG. 4B, respectively, are a 3-D view and a cross-sectional view of the flipchip semiconductor package in accordance with the third preferred embodiment of the invention;

FIG. 5 (PRIOR ART) is a cross-sectional schematic view of a conventional stacked semiconductor package;

FIG. 6 (PRIOR ART) is a cross-sectional schematic view showing a semiconductor package using a leadframe as a chip substrate disclosed by U.S. Pat. No. 5,793,108; and

FIG. 7 (PRIOR ART) is a cross-sectional schematic view showing a stacked flipchip semiconductor package disclosed by U.S. Pat. No. 6,404,043.

### DETAILED DESCRIPTIONS OF THE INVENTION

First Embodiment

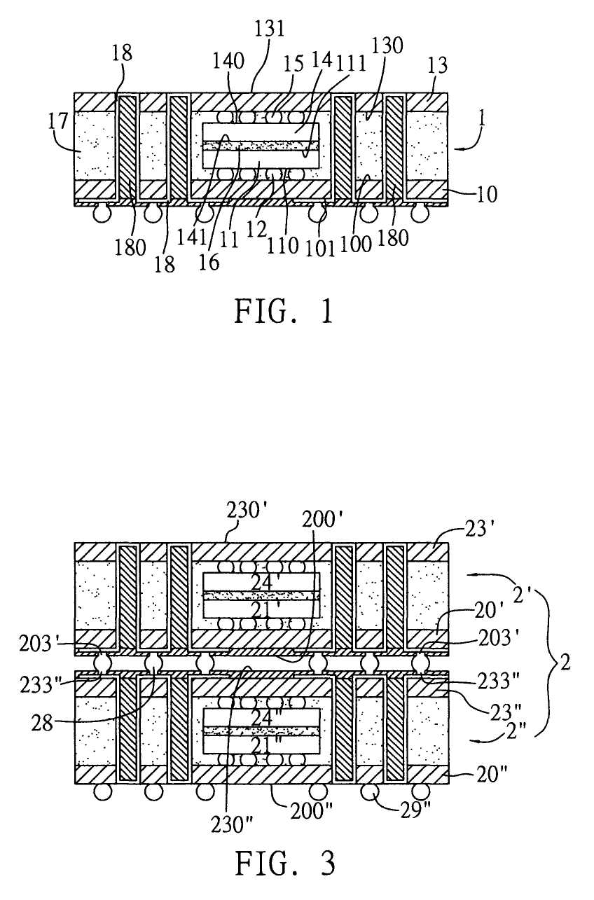

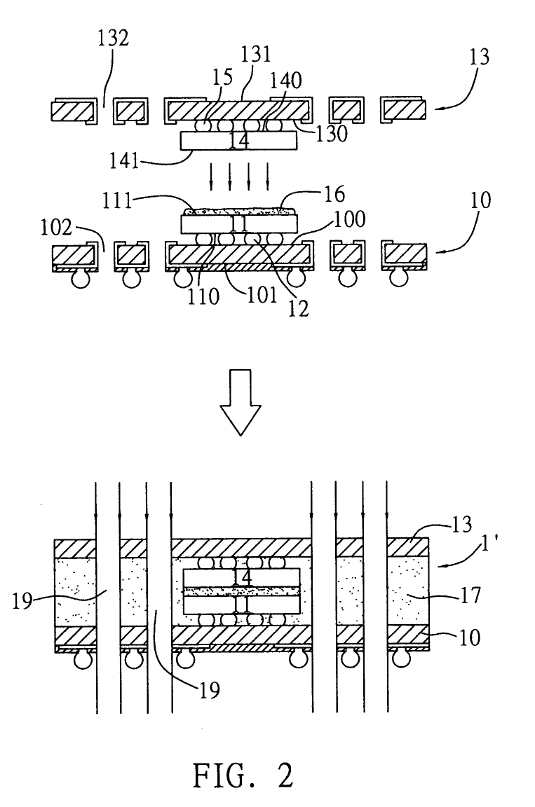

Referring to FIG. 1, the flipchip semiconductor package 1 of the first preferred embodiment of the invention is disclosed, comprising: a first chip carrier 10 accommodating at least one first chip 11 which is electrically connected to the chip carrier 10 via a plurality of solder bumps 12; a second chip carrier 13 accommodating at least one second chip 14 which is electrically connected to the second chip carrier 13 via a plurality of solder bumps 15; an insulating adhesive 16 provided for attaching the first chip carrier 10 in a back-to-back manner to the second chip carrier 13; a resin encapsulating layer 17 which fills in the gaps between the first chip carrier 10 and the second chip carrier 13, in which there is at least one conductive layer 18 formed on the resin encapsulating layer 17 for providing an electrical connecting between the first chip carrier 10 and the second chip carrier 13. Referring now to FIG. 1 and FIG. 2, the first chip carrier 10 and the second chip carrier 13 are made of materials selected from a group consisting of BT (Bismaleimide Triazine) resin, FR-4 resin, FR-5 or polyimide resin, and any other heat stable materials. A FR-4 substrate, a commonly used substrate, comprises two chip carriers, a first chip carrier 10 and a second chip carrier 13, each of which has an active surface 100, 130 and an opposing non-active surface 101, 131. The FR-4 substrate further comprises a plurality of vias 102, 132 extending axially between the active surface 100, 130 and the non-active surface 101, 131, and on the active surface 100, 130 of the chip carrier 10, 13 on which the chip 11, 14, are mounted to, there is formed a plurality of bond pads for electrically connecting the chip 11, 14, allowing signals from the first chip 11 and the second chip 14 to be transmitted to the ball pads mounted on the non-active surface 101, 131 of the chip carrier 10, 13 through the conductive traces (not shown) which extend axially through the vias 102, 103.

The first chip 11 and the second chip 14 can be the same type or different types of chips, such as flash memory, ASIC, SRAM, and DRAM. Each of the two chips have an active surface 110, 140 and an opposing non-active surface 111, 141, and with the formation of a plurality of solder bumps 12, 15 on the active surface 110, 140 during the wafer stage, the first chip 11 is then electrically connected to the first chip carrier 10 while the second chip 14 is electrically connected to the second chip carrier 13.

Alternatively, the foregoing chip carrier can also be selected from a leadframe or a tape carrier. Using a TAB chip carrier, a tape etched with a plurality of lead fingers, as an example, after gold balls (not show) are disposed on each of the active surface 110, 140 for the first chip 11 and the second chip 14, the first chip 11 and the second chip 14 are mounted in a face-down manner on each lead finger (not shown) of the first chip carrier 10 and the second chip carrier 13 respectively. Thus the non-active surface 111 of the first chip 11 can be attached to the non-active surface 141 of the second chip 14 to form a vertically stacked multichip package with two chips 11 14 interposed in between the two chip carriers 10, 13.

The attachment of the first chip 11 to the second chip 14 is achieved by using an adhesive 16. As shown in FIG. 2, after an adhesive 16 made of dielectric materials having high elasticity such as epoxy resin is applied over the non-active surface 111 of the first chip 11 using the conventional screen printing method, the second chip carrier 13 is inverted with the non-active surface 141 of the second chip 14 facing down and being adhered onto the non-active surface 111 of the first chip 11. The high elasticity of the adhesive layer 16 can serve as a buffer that absorbs the large clamping force exerted by the molding equipment against the first chip carrier 10 and the second chip carrier 13 during the molding process, thereby reducing the force sustained by the first chip 11 and the second chip 14. As a result, chip cracking can be avoided.

Since the two non-active surface 111 and 141 of the respective first chip 11 and the second chip 14 are electrically insulated by the insulating adhesive 16, the first chip carrier 10 is joined in a back-to-back manner with the second chip carrier 13, and, as a result, the gap between the two chips can be further reduced in height and thereby meet the requirement of forming an electronic device with as small of size as possible. Also, as the two chip carriers, 10 and 13 are joined in a back-to-back to form a multichip module 1′, both the topmost surface and the lowermost surface of the multichip module 1′ are capable of being electrically connected with other components, thus making it feasible to vertically stack chips in a flip chip package.

The resin encapsulating layer 17 is made of resin materials having low hygrosopicity and low viscosity such as R-MASK. As shown in FIG. 2, after the first chip carrier 10 is joined back-to-back with the second chip carrier 13, the resin will fill in the gaps between the two chip carriers 10 and 13, allowing the periphery and the bottom of the first chip 11 and the second d chip 14 to be completely filled with the resin encapsulating materials. As R-MASK resin has lower hyproscopicity and viscosity compared to the conventional resin, it is unlikely for the formed resin encapsulating layer 17 to absorb too much moisture which can result in popcorn. This resin encapsulating material is also advantageous in that it can completely fill in the gaps between the adjacent solder bumps, and therefore an additional refilling process is not required, simplifying the manufacturing process.

After the resin encapsulating layer 17 is formed, a so-called hole formation technique is applied to form a conductive channel 19 that interconnects the through hole 102 of the first chip carrier 10 and the through hole 132 of the second chip carrier 13. The conductive channel 19 further comprises a metal conductive layer 18 made of copper foil on the inner wall of the conductive channel, and the rest of the cavity is then filled with conductive materials 180 such as copper paste or silver paste or dielectric materials such as epoxy resin. This conductive channel 19 allows the second chip carrier 13 to be electrically connected to the first chip carrier 10.

Second Embodiment

FIG. 3 is a cross-sectional view of a multi-flipchip semiconductor package of a second embodiment of the present invention. The multi-flipchip semiconductor package in this preferred embodiment is almost identical to the foregoing first embodiment, with the only difference being that in this embodiment at least two multichip modules described in the foregoing embodiments are stacked vertically. Since the mutichip module 2′ is formed by joining the first chip carrier 20 to the second chip carrier 23 in a back-to-back manner, both the topmost surface 230′ and the lowermost surface 200′ of the multichip module 2′ are capable of forming a plurality of bond pads 203′ and 233′ thereon which in turn can be electrically connected with other multichip modules or other components. As shown in the drawing, this multichip module of the preferred embodiment further comprises an upper multichip module 2′ and a lower multichip module 2″ in which the first chip carrier 20′ of the upper multichip module 2′ is electrically connected to the second chip carrier 23″ of the lower multichip module 2″ via a plurality of solder bumps 28, thus, allowing the chips encapsulated inside the multichip module 2′ to be electrically connected to the first substrate 20″ of the lower multichip module 2″, which is then electrically connected to external components via a plurality of solder balls 29″ mounted on the back of the first chip carrier 20″.

From this preferred embodiment, it should be apparent that using flip chip technology for attaching chips to a chip carrier following the back-to-back assemblage provided by this invention to create a flipchip multichip module provides a way of vertically stacking chips in a flip-chip package, wherein further modifications and arrangements of the chips in a package are possible. Also, in comparison with conventional wire bonding technology, all the chips in the invention are attached to chip carriers using flip chip technology, thus further assuring the electronic bonding quality of the package.

Third Embodiment

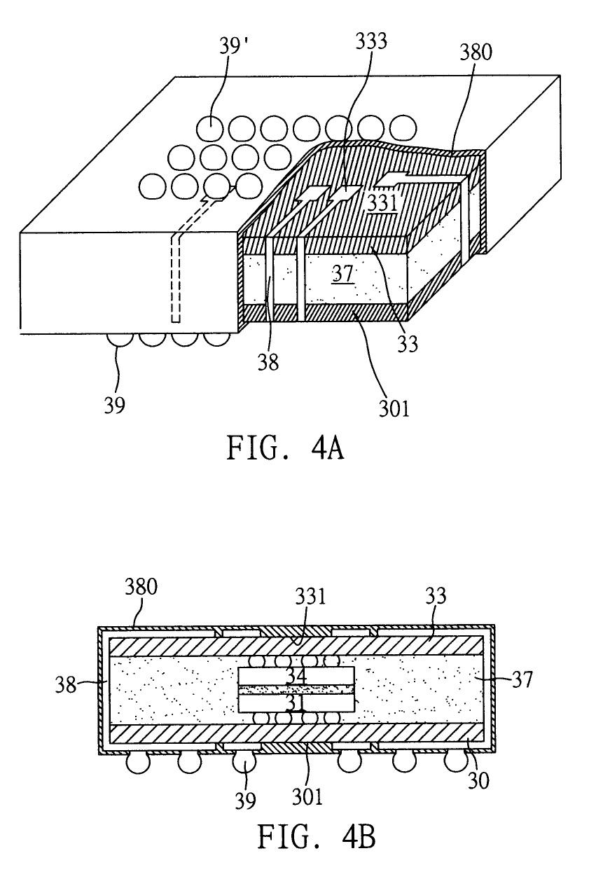

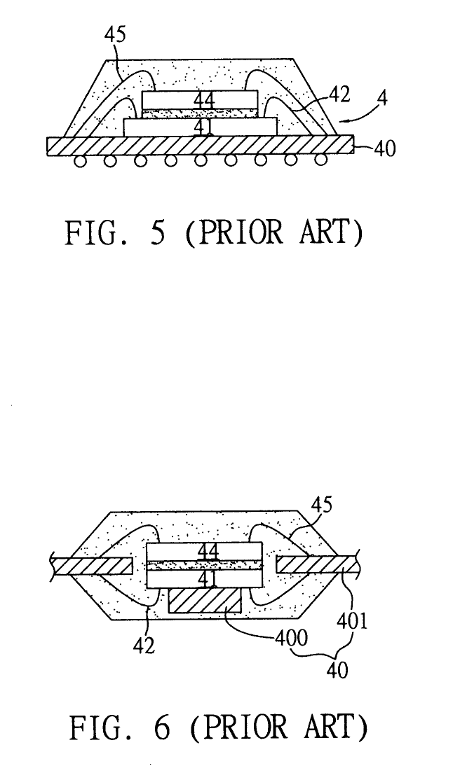

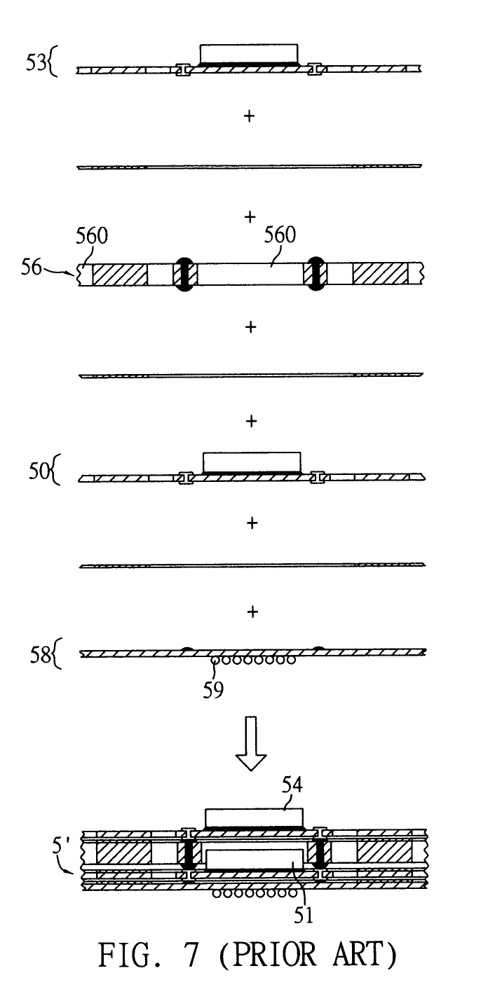

FIGS. 4A and 4B are cross-sectional views showing the flipchip semiconductor package according to the third embodiment of the present invention. The multi-flipchip semiconductor package in this preferred embodiment is almost identical to the foregoing first embodiment, with the only difference being that in this embodiment the resin encapsulating layer 37 filled in between the first chip carrier 30 and the second chip carrier 33 does not have a through conductive channel, but, instead uses electroplating technology to form a plurality of conductive traces 38 which are further encapsulated with a layer of dielectric solder mask for forming electrical connections between the first chip carrier 30 and the second chip carrier 33. The conductive traces 38 each have a starting end that is connected with a bond pad 333 disposed on the back side 331 of the second chip carrier 33, and a terminal end that is connected with a bond pad (not shown) disposed on the back side 301 of the first chip carrier 30. After the signal from the second chip 34 is conducted to the bond pads 333 disposed on the back side 331 of the second chip carrier 33, the signal can be directly conducted to the solder balls 39 disposed on the back side 301 of the first chip carrier 30 via the conductive traces 38. Further the back side 331 of the second chip carrier 33 provides surface for bonding with a plurality of solder balls 39′.

Since the two back-to-back joined chip carriers can be electrically connected with one and another via the conductive traces provided, a through conductive passage is not necessarily required, therefore further reducing the complexity of the conductive traces as the traces do not need to evade the position of the conductive passage.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A flipchip semiconductor package, comprising:
a first chip carrier accommodating at least one first chip having an active surface on which a plurality of solder bumps are formed for electrically connecting the first chip to the first chip carrier, and an opposing non-active surface;
a second chip carrier accommodating at least one second chip having an active surface on which a plurality of solder bumps are formed for electrically connecting the second chip to the second chip carrier, and an opposing non-active surface;
an adhesive layer, applied over the non-active surface of the fist chip allowing the second chip of the second chip carrier to be attached to the first chip of the first chip carrier;
a resin encapsulating layer, filled in between the first chip carrier and the second chip carrier for encapsulating the first chip, the second chip, and the plurality of solder bumps; and
a plurality of conductive through vias extending axially between the first chip carrier, the resin encapsulating layer, and the second chip carrier for electrically connecting the first chip to the first chip carrier via the second chip carrier and the conductive through vias.

2. The flipchip semiconductor package of claim 1, wherein a plurality of solder bumps are disposed on the exposed surface of the second chip carrier for forming electrical connection with another semiconductor package.

3. The flipchip semiconductor package of claim 1, wherein each of the first chip carrier and the second chip carrier is a substrate.

4. The flipchip semiconductor package of claim 1, wherein each of the first chip carrier and the second chip carrier is a tape carrier (TAB).

5. The flipchip semiconductor package of claim 1, wherein the adhesive layer is an insulating adhesive having high elasticity.

6. The flipchip semiconductor package of claim 1, wherein the resin encapsulating layer is made of resin materials having low hygrosocopicity and low viscosity.

7. A flip-chip semiconductor package, comprising:
a first chip carrier accommodating at least one first chip having an active surface on which a plurality of solder bumps are formed for electrically connecting the first chip to first chip carrier, and an opposing non-active surface;
a second chip carrier accommodating at least one second chip having an active surface on which a plurality of solder bumps are formed for electrically connecting the second chip to second chip carrier, and an opposing non-active surface;
an adhesive layer, applied over the non-active surface of the fist chip allowing the second chip of the second chip carrier to be attached to the first chip of the first chip carrier;
a resin encapsulating layer, filled in between the first chip carrier and the second chip carrier for encapsulating the first chip, the second chip, and the plurality of solder bumps; and
a plurality of conductive traces formed between the first chip carrier, the resin encapsulating layer, and the second chip carrier for electrically connecting the first chip to the first chip carrier via each of the conductive traces.

8. The flipchip semiconductor package of claim 7, wherein each of the first chip carrier and the second chip carrier is a substrate.

9. The flipchip semiconductor package of claim 7, wherein each of the first chip carrier and the second chip carrier is a tape carrier (TAB).

10. The flipchip semiconductor package of claim 7, wherein the adhesive layer is an insulating adhesive having high elasticity.

11. The flipchip semiconductor package of claim 7, wherein the resin encapsulating layer is made of resin materials having low hygrosocopicity and low viscosity.

12. The flipchip semiconductor package of claim 7, wherein the conductive traces have one end connected to the ball pads of the second chip carrier and the other end connected to the ball pads of the first chip carrier.
